(19) United States
(12) Patent Application Publication
(10) Pub. No.: US 2013/0248668 A1
(43) Pub. Date: Sep. 26, 2013

(54) LOCKING APPARATUS

(71) Applicants: KAI-MING LU, Tu-Cheng (TW); SHU-GANG SHI, Shenzhen City (CN)

(72) Inventors: KAI-MING LU, Tu-Cheng (TW); SHU-GANG SHI, Shenzhen City (CN)

(73) Assignees: HON HAI PRECISION INDUSTRY CO., LTD, Tu-Cheng (TW); HON FU JIN PRECISION INDUSTRY (ShenZhen) CO., LTD., Shenzhen City (TW)

(21) Appl. No.: 13/477,087

(22) Filed: May 22, 2012

(30) Foreign Application Priority Data
Mar. 23, 2012 (CN) 201210079584.7

(51) Int. Cl. H01L 23/12

(52) U.S. Cl. 248/222.14

(57) ABSTRACT

A locking apparatus includes a bracket, a pressing member, a mounting member, and a screw. The bracket includes two sidewalls and a guiding portion between the sidewalls. The guiding portion includes two opposite side plates and an arc-shaped linking portion. A blocking portion is formed at a joining portion between a top portion of each side plate and a top portion of the corresponding sidewall. An access is defined between the blocking portions. The mounting member includes a rectangular flat top surface and an arc-shaped bottom surface. A screw hole is defined in the mounting member through the top and bottom surface. The mounting member is placed into the guiding portion through the access. The linking portion mates with the bottom surface to guide the top surface facing the access. The screw extends through the pressing member and the access to screw into the screw hole.

### BACKGROUND

1. Technical Field

The present disclosure relates to locking apparatuses and, particularly, to a locking apparatus for mounting photovoltaic modules.

2. Description of Related Art

Photovoltaic modules are mounted to a bracket through locking apparatuses. A locking apparatus includes a plurality of hexagonal nuts received in a slot of the bracket beforehand, and it is often inconvenient to assemble the hexagonal nuts to the locking apparatus because the hexagonal nuts cannot be guided to be correctly and automatically positioned.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an embodiment of a locking apparatus.

FIG. 2 is an exploded, isometric view of the locking apparatus of FIG. 1, but viewed from another perspective.

FIG. 3 is a side plan view of FIG. 1.

### DETAILED DESCRIPTION

The disclosure, including the accompanying drawings in which like references indicate similar elements, is illustrated by way of examples and not by way of limitation. It should be noted that references to “an” or “one” embodiment in this disclosure are not necessarily to the same embodiment, and such references mean at least one.

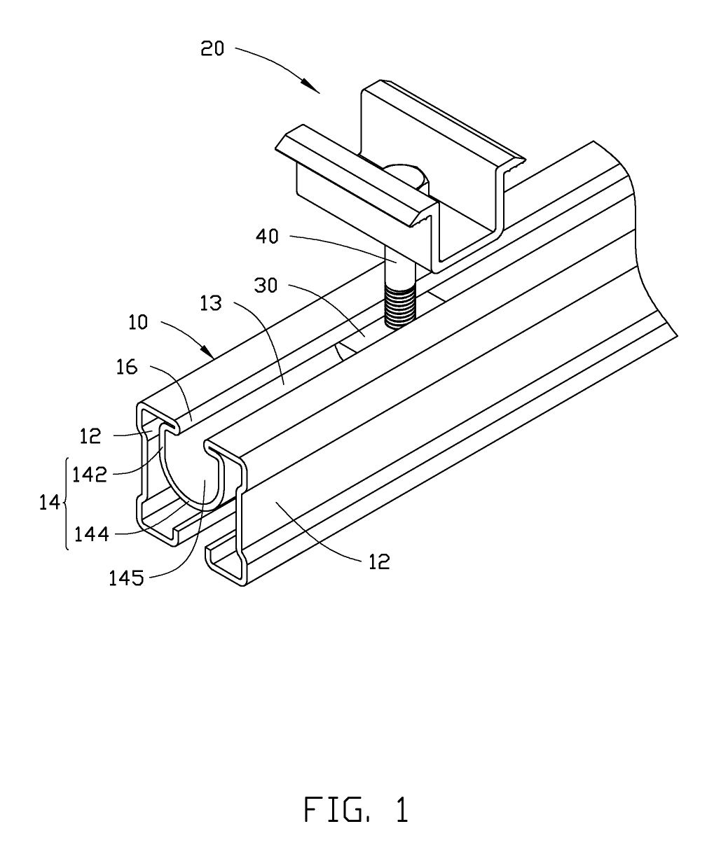

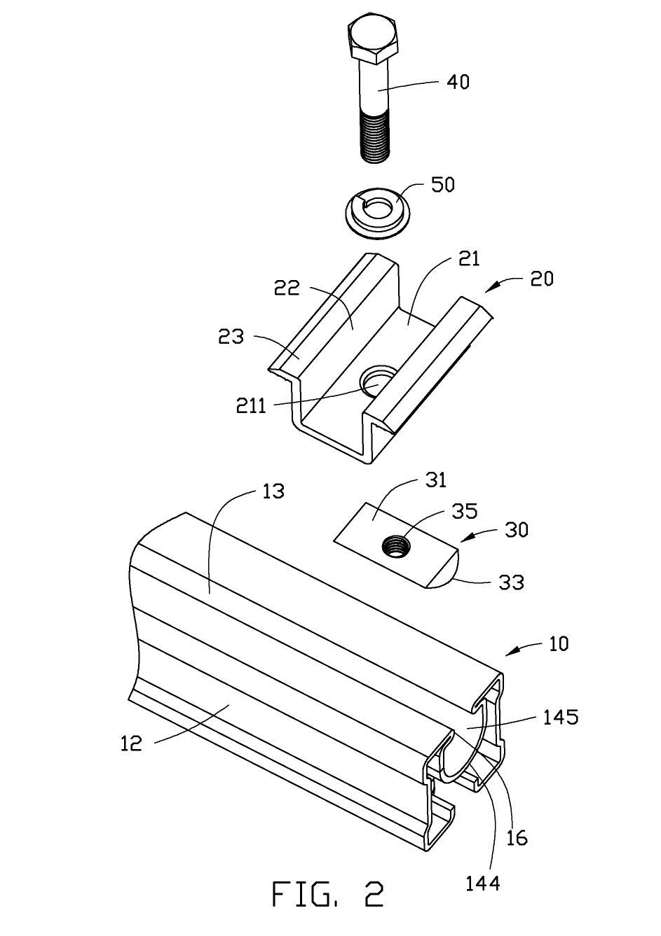

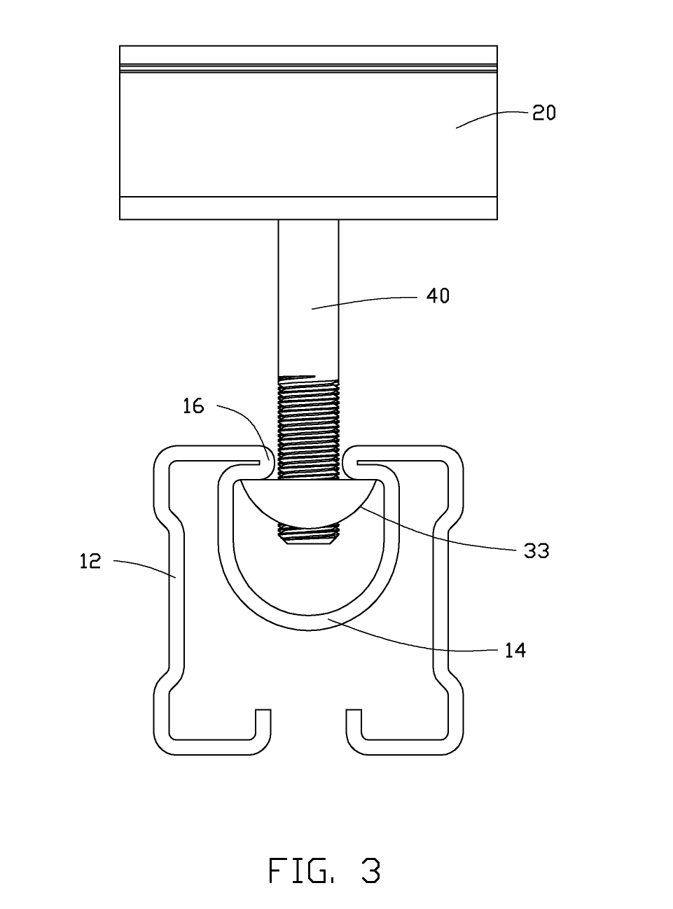

Referring to FIG. 1 to FIG. 3, an embodiment of a locking apparatus for mounting a photovoltaic module is shown. The locking apparatus includes an elongated bracket 10, a pressing member 20, a mounting member 30, a screw 40, and a resilient washer 50.

The bracket 10 includes two opposite side plates 12 and a U-shaped guiding portion 14 connected between the side plates 12. The guiding portion 14 includes two opposite sidewalls 142 extending down from top sides of the corresponding side plates 12, and an arc-shaped linking portion 144 connected between bottom sides of the sidewalls 142. The sidewalls 142 and the linking portion 144 bound a guiding slot 145. A blocking portion 16 is formed at a joining portion between the top side of each side plate 12 and a top side of a corresponding sidewall 142. An access 13 to the guiding portion 14 is formed between the blocking portions 16, communicating with the guiding slot 145.

The pressing member 20 includes a bottom portion 21 and two side portions 22 extending up from opposite sides of the bottom portion 21. A pressing piece 23 extends outward from a top side of each side portion 22, away from the other side portion 22. A through hole 211 is defined in a center of the bottom portion 21.

The mounting member 30 includes a rectangular top surface 31 and an arc-shaped bottom surface 33. A screw hole 35 is defined in a center of the mounting member 30, through the top surface 31 and the bottom surface 33. The largest width between the top surface 31 and the bottom surface 33 is less than the width of the access 13. Therefore, the mounting member 30 can be laterally put in the guiding portion 14 through the access 13.

In assembly, the mounting member 30 is laterally put into the guiding slot 145 through the access 13. The mounting member 30 is adjusted to mate the bottom surface 33 with the linking portion 144, which means the linking portion 144 faces the bottom surface 33. Therefore, the top surface 31 faces the access 13. The width of the mounting member 30 is less than the distance between the sidewalls 142. Therefore, the mounting member 30 can be received between the sidewalls 142 horizontally. The screw 40 extends through the washer 50, the through hole 211, and the access 13 in that order, to screw into the screw hole 35. A side of the photovoltaic module can be firmly sandwiched between the pressing piece 23 and the bracket 10 by adjusting a length of the screw 40 screwing into the screw hole 35. The width of the mounting member 30 is larger than the width of the access 13, which can prevent the mounting member 30 from releasing from the bracket 10. The length of the mounting member 30 is larger than the distance between the sidewalls 142, which can avoid the mounting member rotating in the guiding slot 145.

In this embodiment, when the mounting member 30 is put into the guiding slot 145, the linking portion 144 can mate with the bottom surface 33, to guide the mounting member 30 to make the top surface 31 be correctly and automatically positioned. The screw 40 can be conveniently assembled to the mounting member 30.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A locking apparatus, comprising:
a bracket comprising two side plates and a substantially U-shaped guiding portion, the guiding portion comprising two sidewalls extending down respectively from top sides of the side plates, and an arc-shaped linking portion connected between bottom sides of the sidewalls, the sidewalls and the linking portion bounding a guiding slot, wherein a blocking portion is formed at a joining portion between the top side of each of the side plates and a top side of a corresponding sidewall, an access communicating with the guiding slot is defined between the blocking portions;
a pressing member defining a through hole;
a mounting member comprising a rectangular top surface and an arc-shaped bottom surface, the mounting member defining a screw hole extending through the top surface and the bottom surface; and
a screw;
wherein when the mounting member is laterally put into the guiding slot through the access, the mounting member is adjusted to mate the bottom surface with the linking portion, to make the top surface of the mounting member face the access, the screw extends through the through hole of the pressing member, the access, to screw into the screw hole.

2. The locking apparatus of claim 1, wherein a largest width between the top surface and the bottom surface of the mounting member is less than a width of the access.

3. The locking apparatus of claim 1, wherein a width of the mounting member is less than a distance between the sidewalls.

4. The locking apparatus of claim 1, wherein a width of the mounting member is larger than the access.

5. The locking apparatus of claim 1, wherein a length of the mounting member is larger than a distance between the sidewalls.
